(19) United States
(12) Patent Application Publication
(10) Pub. No.: US 2017/0186674 A1
(43) Pub. Date: Jun. 29, 2017

(54) SEMICONDUCTOR PACKAGES AND METHODS FOR FORMING SAME

(71) Applicant: STMICROELECTRONICS PTE LTD, Singapore (SG)

(72) Inventor: Jing-En Luan, Shenzhen (CN)

(21) Appl. No.: 15/019,617

(22) Filed: Feb. 9, 2016

(30) Foreign Application Priority Data
Dec. 28, 2015 (CN) 201511001298.9

(51) Int. Cl. H01L 23/495; H01L 21/56; H01L 23/31

(52) U.S. Cl. CPC H01L 23/49568; H01L 23/49513; H01L 23/3121; H01L 21/561

(57) ABSTRACT

One or more embodiments are directed to a semiconductor package that includes an integrated heatsink and methods of forming same. In one embodiment, the semiconductor package includes a semiconductor die coupled to a first surface of a die pad. A heatsink is coupled to a second surface of the die pad. Encapsulation material is located around the die and die pad and over a portion of the heatsink. A bottom portion of the heatsink may remain exposed from the encapsulation material. Furthermore, a portion of the heatsink may extend from a side of the encapsulation material.

### TECHNICAL FIELD

The present disclosure is directed to semiconductor packages and methods for forming same.

### DESCRIPTION OF THE RELATED ART

Semiconductor packages are subject to considerable heat during operation. This is particularly the case with power device packages, which include power devices that operate at high currents and/or voltages levels, thereby generating a significant amount of heat.

To assist in removing heat from the package body, power device packages are often coupled to an external heat spreader. An external heat spreader, however, is limited in the amount of heat that it can remove. That is, the heat spreader is only able to remove heat that it receives from the package. Thus, improvements within the package are desired to adequately deliver the heat generated by the package to the heat spreader.

Generally described, power device packages typically include a semiconductor die mounted to a die pad of a leadframe. A dielectric material, such as encapsulation material, covers the semiconductor die and the die pad. Typically, however, a bottom surface of the die pad remains exposed. The die pad is a thermally conductive material that receives heat generated by the die. The bottom surface of the die pad may be coupled to a heat spreader to transfer the heat away from the package.

Recently, the thickness of the die pad has been increased, in part, to improve the thermal dynamics of the package. That is, to improve heat transfer from the package to the heat spreader. This, however, significantly increases the cost of the packages. Thus, further improvements are desired.

### BRIEF SUMMARY

One or more embodiments are directed to a semiconductor package that includes an integrated heatsink and methods of forming same. In one embodiment, the semiconductor package includes a semiconductor die coupled to a first surface of a die pad and a heatsink coupled to a second surface of the die pad. Encapsulation material is located around the die and die pad and over a portion of the heatsink. A bottom portion of the heatsink may remain exposed from the encapsulation material for coupling to another thermal component, such as a heat spreader. Furthermore, a portion of the heatsink may extend from a side of the encapsulation material.

Another embodiment is directed to a method comprising coupling heatsinks to first surfaces of die pads of a leadframe and coupling semiconductor dice to second surfaces of the die pads. The second and first surfaces of the die pads are opposite each other. The method further includes electrically coupling the semiconductor dice to leads of the leadframe, such as by conductive wires. The method further includes encapsulating the semiconductor dice, the die pads, portions of the leads, and portions of the heatsinks in an encapsulation material. One of the surfaces of each of the heatsinks remaining exposed from the encapsulation material.

### BRIEF DESCRIPTION OF THE SEVERAL VIEWS OF THE DRAWINGS

In the drawings, identical reference numbers identify similar elements. The sizes and relative positions of elements in the drawings are not necessarily drawn to scale.

FIGS. 1A-1D illustrate various views of a semiconductor package in accordance with one embodiment.

FIGS. 2A is a top down view of a leadframe strip.

FIGS. 2B-2E illustrate cross-section views of various stages of an assembly process for forming semiconductor packages, such as the semiconductor package of FIGS. 1A-1D, in accordance with an embodiment of the present disclosure.

### DETAILED DESCRIPTION

It will be appreciated that, although specific embodiments of the present disclosure are described herein for purposes of illustration, various modifications may be made without departing from the spirit and scope of the present disclosure.

In the following description, certain specific details are set forth in order to provide a thorough understanding of various aspects of the disclosed subject matter. However, the disclosed subject matter may be practiced without these specific details. In some instances, well-known structures and methods of semiconductor processing, such as semiconductor power devices, comprising embodiments of the subject matter disclosed herein have not been described in detail to avoid obscuring the descriptions of other aspects of the present disclosure.

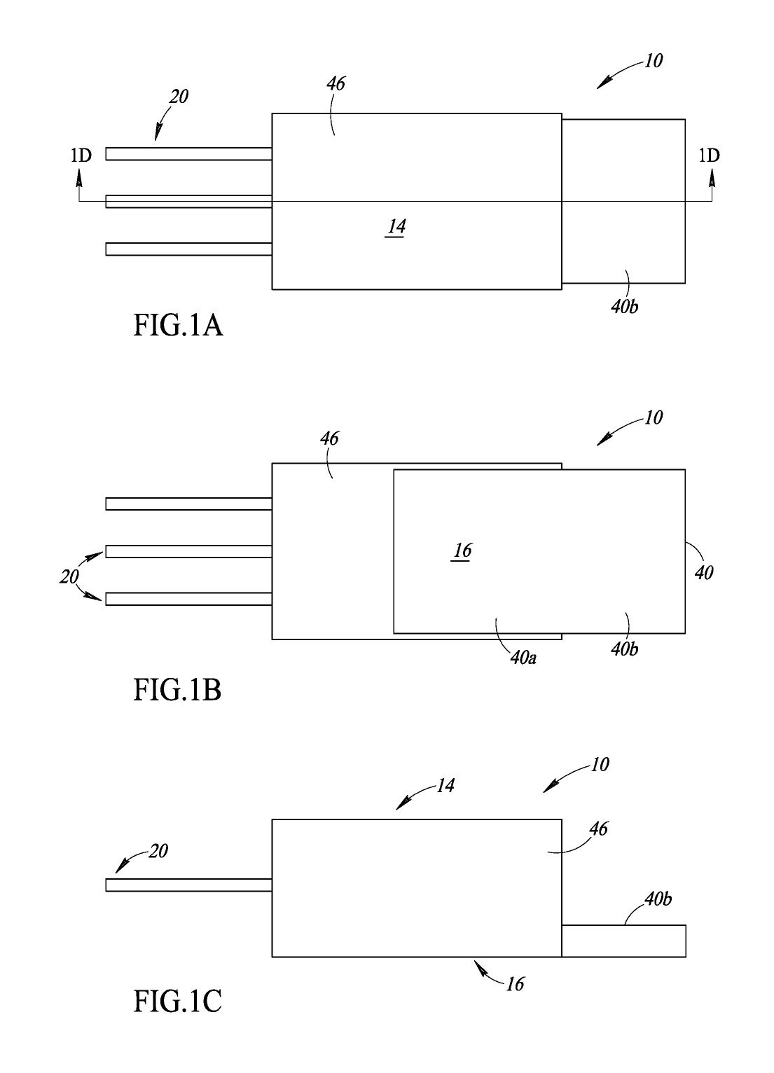

FIG. 1A is a top view of a semiconductor package 10 according to one embodiment of the disclosure. FIGS. 1B and 1C are bottom and side views, respectively, and FIG. 1D is a cross-section view of the semiconductor package 10 of FIG. 1A.

The semiconductor package 10 includes a package body 12 having a first outer surface 14, a second outer surface 16 that is opposite the first outer surface, and outer side surfaces. As best shown in FIG. 1D, the package 10 has is a leadframe that includes a die pad 18 and a plurality of leads 20. In particular, the leads 20 include first portions 20a that are located in the package body 12 and second portions 20b that extend from a side surface of the package body 12.

The second portions 20b of the leads 20 form electrodes for electrically coupling, for example by soldering, to electrical contacts on a surface of a printed-circuit board (PCB) (not shown) as is well known in the art. For instance, the package 10 may be a power device package for mounting to a printed circuit board (PCB), for example by through-hole technology (THT) such that the leads 20 of the package 10 form electrodes that are inserted into through-holes of the PCB. Alternatively, the electrodes may be soldered to the PCB as is well known in the art.

The die pad 18 has first and second surfaces 30, 32 and a distance between the first and second surfaces 30, 32 forms a first thickness therebetween.

The leads 20 have the same thickness as the die pad 18. That is, the leadframe from which the plurality of leads 20 and the die pad 18 are formed has a single thickness at least for the leads and the die pads. In one embodiment, the thickness of the leads 20 and the die pad 18 is 0.3 millimeters. The leadframe is made of a conductive material and may be a metal material, such as copper or a copper alloy.

A semiconductor die 36 is coupled to the first surface 30 of the die pad 18 by a first adhesive material 38. The semiconductor die 36 includes semiconductor material, such as silicon, and integrates any electronic component. The electronic component may be a power device, such as a power diode or a power MOSFET. The first adhesive material 38 may be any material configured to secure the semiconductor die 36 to the die pad 18, such as solder, glue, film, paste, tape, epoxy, combinations thereof, or any suitable material. The first adhesive material 38 may be an electrically conductive material and/or a thermally conductive material. In one embodiment, the first adhesive material 38 is a low melting temperature solder, such as those that begin to melt at temperatures of less than 185° C., and in one embodiment begins to melt at temperatures of less than or equal to 183° C.

The semiconductor die 36 is electrically coupled to at least one of the leads 20 by electrical conductive wires 41 as illustrated in FIG. 1D. In particular, a first end of the conductive wire 41 is coupled to a bond pad of the die 36 and a second end is coupled to the first portion 20a of the lead 20. The conductive wire 41 may be any conductive material to electrically couple the semiconductor die 36 to the leads 20 and may be a metal material, such as aluminum, gold, copper, and alloys thereof. Although not shown in the cross-section view of FIG. 1D, one of the leads 20, such as the center lead, may be coupled to or integral with the die pad 18, which in one embodiment forms a drain electrode of a power MOSFET, while the outer leads may form the source and gate electrodes of the power MOSFET.

Although three leads 20 are shown in FIG. 1A, the semiconductor package 10 may include any number of leads, for example two or more leads, as is well known in the art.

Although not shown, at least a portion of the surfaces of the leads 20 may be plated with one or more conductive layers. The one or more conductive layers are nanolayers or microlayers and may be of any conductive material. In one embodiment, the one or more conductive layers are a plurality of stacked metal layers, such as Ni/Pd/Ag, Ni/Pd/Au—Ag alloy, or Ni/Pd/Au/Ag. The one or more conductive layers may protect the leadframe material from corrosion and may assist with bonding conductive features, such as bonding the conductive wire 41 to the leads 20.

The package 10 further includes a heatsink 40 that is coupled to the second surface 32 of the die pad 18 by a second adhesive material 42. Preferably, the second adhesive material 42 is thermally conductive and may also be electrically conductive. The second adhesive material 42 may be any of the adhesive materials listed above in reference to the first adhesive material 38. The second adhesive material 42 may have a higher melting temperature than the first adhesive material 38. For instance, the second adhesive material 42 may begin to melt at temperatures greater than or equal to 185° C. and in one embodiment begins to melt at temperatures greater than or equal to 190° C. Alternatively, the second adhesive material 42 may be the same adhesive material as the first adhesive material 38.

The heatsink 40 is any thermally conductive material. For instance, the heatsink 40 may be a metal material, like copper and aluminum, and alloys thereof, ceramic, or any other thermally conductive material. The heatsink 40 receives heat generated by the semiconductor die 36 during its operation. That is, the heatsink receives heat received from the semiconductor die 36 through the die pad 18 and the first and second adhesive materials 38, 42.

The heatsink 40 has a first portion 40a that is below the die pad 18 and partially covered by the package body 12, and second portion 40b that extends beyond the package body 12. In particular, a first surface of the heatsink 40 at the first portion 40a is coupled to the die pad 18. A second surface of the heatsink 40 forms a portion of the second outer surface 16 of the package body 12.

The dimensions of the heatsink 40 are any dimensions that allow for suitable removal of some of the heat generated by the semiconductor die 36. In one embodiment, the first portion 40a of the heatsink 40 may cover the entire second surface 32 of the die pad 18. In that regard, the heatsink 40 has a maximized surface area to mate with the die pad 18 for removing heat received by the die pad 18 from the semiconductor die 36. In that regard, the first portion 40a of the heatsink 40 may be the same size as or larger than the die pad 18. The second portion 40b of the heatsink 40 may be larger than the first portion 40a of the heatsink 40.

The heatsink 40 may also provide support for the semiconductor die 36 along with the die pad 18. That is, in some embodiments in which the leadframe material is thin and does not adequately support the semiconductor die 36 during assembly processing, the heatsink 40 may provide further support for the semiconductor die 36. In general, the thickness of the heatsink 40 (i.e., the distance between the first and second surfaces) is any thickness suitable to transfer heat from the semiconductor die 36 to outside of the package 10. In some embodiments, the heatsink 40 has a thickness of about 2 to 4.5 millimeters.

The package body 12 is formed, in part, by an encapsulation material 46 that is around the semiconductor die 36, conductive wires 41, die pad 18, and portions of the leads 20 and the heatsink 40. In particular, the semiconductor die 36, conductive wires, and die pad 18 are fully encapsulated in the encapsulation material 46. The first portions 20a of the leads 20 are located in the encapsulation material 46, while the second portions 20b extend from a side surface of the encapsulation material 46, which forms a side surface of the package body 12. The encapsulation material 46 is located over the first surface of the first portion 40a of the heatsink 40 and alongside surfaces of the first portion 40a of the heatsink 40. The second surface of the first portion 40a, however, remains exposed from the encapsulation material 46. Similarly, the second portion 40b of the heatsink 40 remains exposed from the encapsulation material 46.

The encapsulation material 46 is a dielectric material that protects the electrical components of the semiconductor die 36 and conductive wires 41 from damage, such as corrosion, physical damage, moisture damage, or other causes of damage to electrical devices and materials. In one embodiment, the encapsulation material 46 is a polymer, such as an epoxy mold.

As mentioned above, the first surface of the first portions of the heatsink 40 is covered by the encapsulation material 46, while the second surface remains exposed from the encapsulation material 46. That is, the entire second surface of the heatsink 40 is exposed from the encapsulation material 46. The second surface of the heatsink 40 may be coplanar with the surface of the encapsulation material 46 at the second outer surface 16 of the package body 12.

The heatsink 40 may be configured to be coupled to a heat spreader (not shown) that is external to the package. That is, the heat spreader may be coupled to the second surface of the heatsink. In some embodiments, the second portion 40b of the heatsink 40 may include an opening (not shown) for receiving a fastener for coupling the heatsink 40 to the heat spreader. Alternatively, the heatsink 40 may be secured to the heat spreader by a clip or adhesive material. The heat spreader further assists in removing heat from the package 10.

By having a single gauge leadframe package or a leadframe having a single thickness for the leads and the die pad as described above, the assembly process for forming the leadframe is reduced. Furthermore, costs associated with forming the leadframe used to form the package have been reduced. Additionally, by having a single gauge leadframe, cracking of the semiconductor die mounted to the leadframe can be reduced. In particular, due to differing coefficients of thermal expansion (CTE) between the semiconductor die and the die pad has resulted in thinner die, such as die having a thickness of 100 microns or less, to crack. By providing a thin die pad with a heatsink coupled thereto within the package itself, some flexing is allowed within the package itself, thereby reducing stresses that may occur within the package. That is, due to the reduced thickness of the die pad, the die pad is more able to flex than with thicker die pads. Furthermore, the heatsink may act as a support structure for the die pad during flexing. In that regard, any expansions and contractions due to differing CTE between the die and the die pad may be better accommodated in the present package than is provided in the prior art packages.

Furthermore, by forming the package with the heatsink integrated in the package body, various benefits are obtained. As mentioned above, the heatsink provides support for the semiconductor die during the assembly process. Additionally, the size, such as the thickness, of the heatsink may be determined to accommodate the needs of the package, such as the type of semiconductor die to be assembled in the package or for thermal requirements for the application of the package. Finally, having the heatsink in the package body provides a simplified single unit for customers.

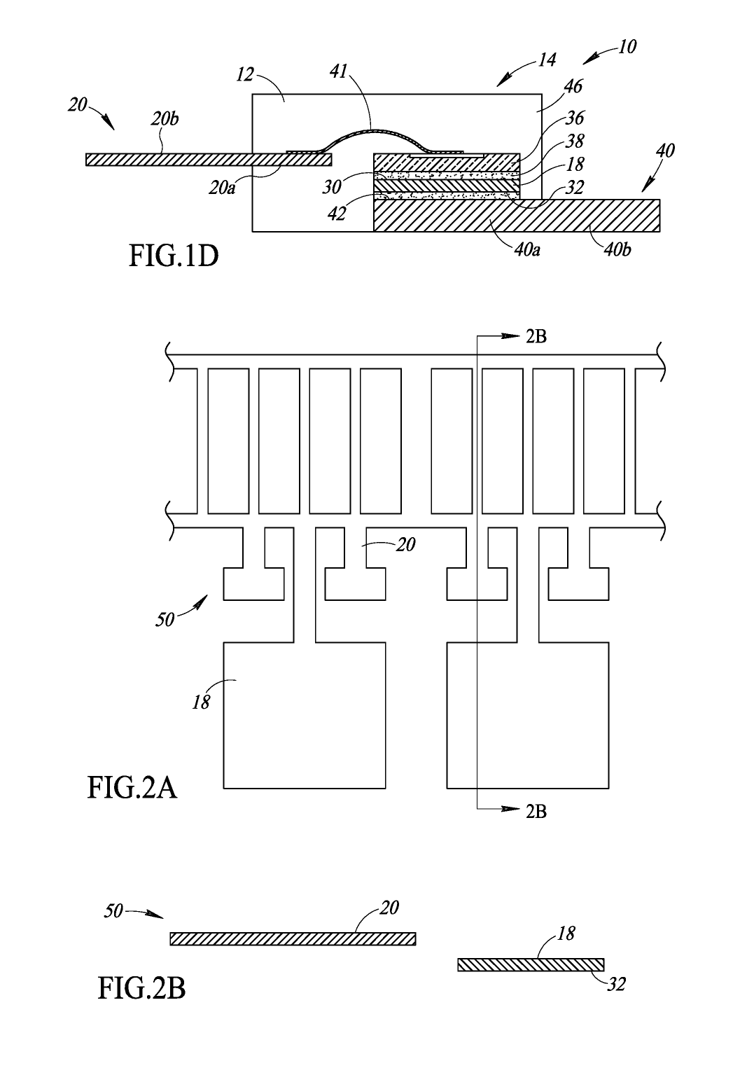

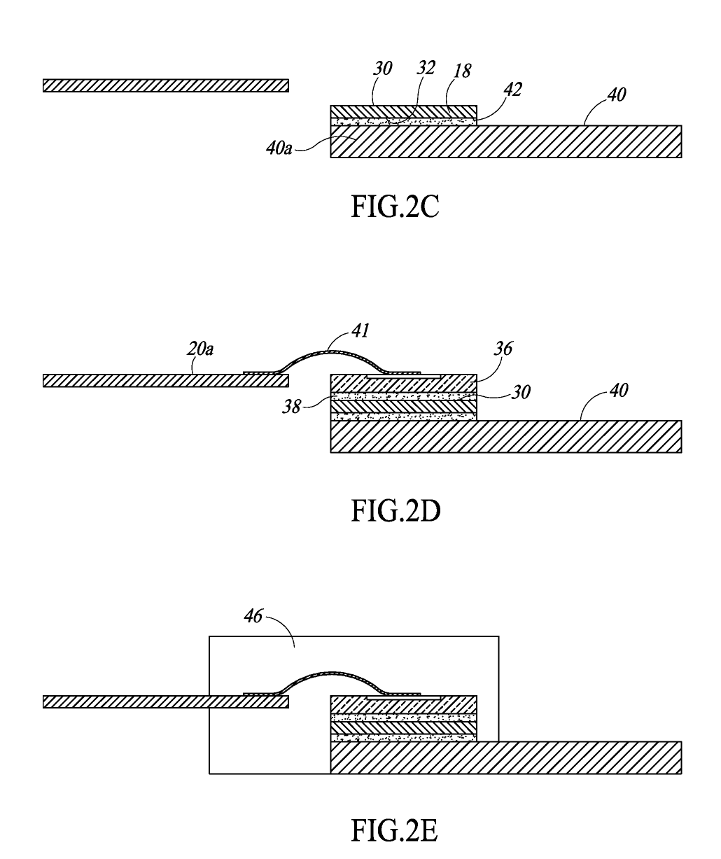

FIG. 2A is a partial top view of a leadframe strip 50 used to form a plurality of individual packages, such as the package 10 of FIGS. 1A-1D. Although only two individual package portions of the leadframes are shown, each with a die pad 18 and three leads 20 associated with the die pad 18, it is to be appreciated that the leadframe strip 50 may include any number of individual package portions of the leadframe in a single strip or matrix form. The leads 20 are coupled together by connecting bars which will be removed during a singulation step upon assembly of the individual packages.

FIGS. 2B-2E illustrate cross-section views of various stages of the assembly process for forming the package 10 of FIG. 1 in accordance with one embodiment of the disclosure. As shown in FIG. 2B, the thickness of the leadframe strip 50 is uniform, which is also referred to as a single gauge leadframe. That is, the die pad 18 and the leads 20 of the leadframe strip 50 have the same thickness.

As shown in FIG. 2C, the heatsink 40 is coupled to the second surface 32 of the die pad 18. In particular, the second adhesive material 42 is applied to at least one of the second surface 32 of the die pad 18 and the first portion 40a of the heatsink 40. The first portion 40a of the heatsink 40 is placed on the second surface 32 of the die pad 18, which are coupled together by the second adhesive material 42. In some embodiments, heat and/or pressure may be applied to at least one of the heatsink 40 and the die pad 18 to assist in the coupling of the heatsink 40 with the die pad 18. As mentioned above, the heatsink 40 may provide further support for the die pad 18 during subsequent processing, such as during die attach as will be described below.

As shown in FIG. 2D, the semiconductor die 36, such as a semiconductor die that integrates a power device, is coupled to the first surface 30 of the die pad 18. In particular, the first adhesive material 42 is applied to at least one of a back side of the semiconductor die 36 and the first surface 30 of the die pad 18. The semiconductor die 36 is placed on the die pad 18. Heat and/or pressure may be applied to at least one of the semiconductor die 36 and the die pad 18 to assist in the coupling of the semiconductor die 36 with the die pad 18.

The semiconductor die 36 is electrically coupled to first portion 20a of the leads 20. That is, a first end of the conductive wire 41 is coupled to a bond pad of the semiconductor die 36, and a second end of the conductive wire 41 is coupled to the first portion 20a of the lead 20. Although not shown, more than one conductive wire may be coupled between the semiconductor die 36 and the leads 20.

As shown in FIG. 2E, the encapsulation material 46 is formed around the semiconductor die 36, the conductive wires 41, the first portion 40a of the leads 20, the die pad 18 and a portion of the heatsink 40. For instance, a molding process may be used to form the encapsulation material 46. That is, the leadframe strip 50 may be placed in a mold and encapsulation material 46 is injected into the mold. The encapsulation material 46 may harden over time, which may also include a curing step. As mentioned above, the encapsulation material 46 may be a polymer, such as epoxy mold.

The leadframe strip 50 is then singulated to form individual packages 10, forming a plurality of individual packages. The singulation may occur by various dicing methods, including sawing, punching, and laser cutting. As is well understood in the art, the connecting bars of the leadframe strip are removed during the singulation process thereby electrically isolating the leads from each other.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor package, comprising:
a die pad having a first surface and a second surface separated from the first surface by a first thickness;
a plurality of leads having a second thickness that is the same as the first thickness;
a first adhesive material having a first melting temperature;
second adhesive material a second melting temperature, the second melting temperature of the second adhesive being higher than the first melting temperature of the first adhesive material;
a semiconductor die coupled to the first surface of the die pad by the first adhesive material, the semiconductor die electrically coupled to the plurality of leads;
a heatsink coupled to the second surface of the die pad by the second adhesive material; and
encapsulation material over the semiconductor die, the die pad, and around portions of the heatsink and the plurality of leads.

2. The semiconductor package of claim 1 wherein the heatsink extends outward from a side surface of the encapsulation material.

3. The semiconductor package of claim 1 wherein an outer surface of the package is formed by a surface of the encapsulation material and a surface of the heatsink.

4. The semiconductor package of claim 3 wherein the surface of the encapsulation material and the surface of the heatsink are coplanar.

5. The semiconductor package of claim 1, further comprising conductive wires that electrically couple the semiconductor die to the plurality of leads.

6. The semiconductor package of claim 1 wherein the heatsink is a metal material or ceramic.

7. The semiconductor package of claim 1, wherein the second adhesive material is a conductive adhesive material.

8. A method, comprising:
coupling heatsinks to first surfaces of die pads of a leadframe using a first adhesive material having a first melting temperature;
coupling semiconductor dice to second surfaces of the die pads using a second adhesive material having a second melting temperature, the second melting temperature being less than the first melting temperature, the second surfaces being opposite the first surfaces;
electrically coupling the semiconductor dice to leads of the leadframe; and
encapsulating the semiconductor dice, the die pads, portions of the leads, and portions of the heatsinks in an encapsulation material, wherein surfaces of the heatsinks are exposed from the encapsulation material.

9. The method according to claim 8 wherein coupling the heatsinks comprises dispensing the first adhesive material on at least one of the surfaces of the die pads and surfaces of the heatsinks, and placing the heatsinks on the first surface of the die pads.

10. The method according to claim 8 wherein the die pads of the leadframe have first thicknesses and the leads of the leadframe have second thicknesses, wherein the first thicknesses are the same as the second thicknesses.

11. The method according to claim 8 wherein coupling heatsinks to first surfaces die pads of a leadframe comprises coupling first portions of the heatsinks to the first surfaces of the die pads such that second portions of the heatsinks extend beyond the die pads.

12. The method according to claim 8, further comprising dicing through the leadframe and encapsulation material and forming individual semiconductor packages.

13. The method according to claim 12 wherein the exposed surfaces of the heatsinks are coplanar with a surface of the encapsulation material.

14. A semiconductor package, comprising:
a die pad having a first surface and a second surface;
a plurality of leads;
a semiconductor die coupled to the first surface of the die pad and electrically coupled to the plurality of leads;
a heatsink coupled to the second surface of the die pad by a conductive adhesive; and
encapsulation material covering the semiconductor die, the die pad, and at least a portion of one or more side surfaces of the heatsink.

15. The semiconductor package of claim 14 wherein the encapsulation material covers side surfaces of a first portion of the heatsink, wherein side surfaces of a second portion of the heatsink remain exposed from the encapsulation material.

16. The semiconductor package of claim 14 wherein the semiconductor die is coupled to the first surface of the die pad by an adhesive material, the adhesive material being different from the conductive adhesive material.

17. The semiconductor package of claim 16, wherein the adhesive material has a lower melting temperature than the conductive adhesive material.
